(19) United States
(12) Patent Application Publication
(10) Pub. No.: US 2008/0056013 A1
(43) Pub. Date: Mar. 6, 2008

(54) Method and Related Apparatus Capable of Improving Endurance of Memory

(76) Inventors: Ching-Yuan Lin, Hsin-Chu Hsien (TW); Yen-Tai Lin, Hsin-Chu City (TW)

Correspondence Address: NORTH AMERICA INTELLECTUAL PROPERTY CORPORATION, P.O. BOX 506, MERRIFIELD, VA, 22116, US

(21) Appl. No.: 11/936,095

(22) Filed: Nov. 7, 2007

Related U.S. Application Data
(62) Division of application No. 11/531,278, filed on Sep. 13, 2006.
(60) Provisional application No. 60/766,288, filed on Jan. 8, 2006.

(51) Int. Cl. G11C 16/04

(52) U.S. Cl. 365/185.33

(57) ABSTRACT

A method capable of improving endurance of memory includes detecting whether a record cell is the last non-programmed record cell of a set of record cells that includes the record cell. The method includes erasing the corresponding set of multi-time programmable memory blocks and erasing the set of record cells, if the record cell is the last non-programmed record cell of the set of record cells that includes the record cell. The method further includes programming the record cell corresponding to a first non-programmed record cell in the set of record cells if the non-programmed record cell is not the last non-programmed record cell of the set of record cells.

### CROSS REFERENCE TO RELATED APPLICATIONS

This is a division of pending U.S. patent application Ser. No. 11/531,278 filed Sep. 13, 2006, which claims the benefit of U.S. Provisional Application No. 60/766,288, filed Jan. 8, 2006, and included herein by reference.

### BACKGROUND OF THE INVENTION

1. Field of the Invention

The present invention relates to a method and related apparatus capable of improving endurance of memory, and more particularly, to a method and a memory utilizing a plurality of sets of multi-time programmable memory blocks and a plurality of sets of record cells to improve endurance of memory.

2. Description of the Prior Art

Because of the non-volatile characteristic of non-volatile memory, non-volatile memory has been applied in various electrical products, such as digital cameras, mobile phones, video game consoles, and personal digital assistants.

Non-volatile memory is divided into two kinds. One is mask ROM, which cannot be altered after being written. The other is flash memory, which can be altered after being written. The most famous usage of mask ROM is applied on Nintendo 64 game software. The primary usage of flash memory is applied on a mobile phone's chip. Generally speaking, some memory devices, such as hard disk drives, flash memory, and one-time programmable (OTP) memory, can be classified as non-volatile memories because data stored in these devices is not lost when power is shut down. Flash memory and OTP memory are two kinds of non-volatile memory that are more popular. Flash memory and OTP memory respectively control a threshold voltage of their memory cells to store binary data such as “0” or “1”. The main difference between flash memory and OTP memory is that data stored in flash memory can be updated many times and OTP memory is one-time programmable. Once data is written into a memory cell of OTP memory, it is impossible to update the data stored in the memory cell.

Please refer to FIG. 1, which is a diagram of a structure of a flash memory cell 10 according to the prior art. The flash memory cell 10 includes a substrate 12, a source 13, a drain 14, a floating gate 15, and a control gate 16. An oxide layer 18 is formed between the channel 19 and the floating gate 15. The control gate 16 is connected to a reference voltage Vcg. The substrate 12 is connected to a ground voltage GND (normally Ground 0V), the source 13 is connected to a voltage Vs, and the drain 14 is connected to a voltage Vd. If the substrate 12 is a P-substrate, then the source 13 and the drain 14 are both N-doped. If the substrate 12 is an N-substrate, then the source 13 and the drain 14 are both P-doped.

Data stored in the flash memory cell 10 is determined by electrons stored in the floating gate 15 because the electrons stored in the floating gate 15 will change the corresponding threshold voltage of the flash memory cell 10. A lower threshold voltage of the flash memory cell 10 corresponds to fewer electrons in the floating gate 15 and corresponds to a binary number “1”. And a higher threshold voltage of the flash memory cell 10 corresponds to more electrons in the floating gate 15 and corresponds to a binary number “0”.

Please continue to refer to FIG. 1. Before writing data into the flash memory cell 10, the flash memory cell 10 must be erased. Currently, the most well-known and commonly used flash memory erasing method is called Fowler-Nordheim tunneling (FN tunneling). FN tunneling is mentioned in many documents, such as U.S. Pat. No. 5,642,311 “Overerase correction for flash memory which limits overerase and prevents erase verify errors”. When an erasing procedure is performed on the flash memory cell 10, a voltage pulse is continually applied to the flash memory cell 10. The erasing voltage pulse generates an electromotive force (EMF) with a negative potential difference between the control gate 16 and the drain 14 of the flash memory cell 10. For example, when an erasing voltage pulse is applied to the flash memory cell 10, the reference voltage Vcg of the control gate 16 is −10 volts, the voltage Vd of the drain 14 is +5.5 volts, and the source 13 is floating. With the above erasing procedure, electrons accumulated in the floating gate 15 of the flash memory cell 10 are reduced because the electrons pass through a thin dielectric layer of the flash memory cell 10 to cause a reduction of the threshold voltage of the flash memory cell 10.

Please refer to FIG. 2. FIG. 2 is a diagram of a flash memory device 20 according to the prior art. The flash memory device 20 includes a multi-time programmable memory area 22, a control circuit 24, a row decoder 27 and a column decoder 28. The multi-time programmable memory area 22 includes M multi-time programmable memory blocks 231-23M, wherein each multi-time programmable memory block is constructed of a plurality of multi-time programmable memory cells. Each multi-time programmable memory cell is used for storing data of one bit. As shown in FIG. 1, the flash memory cell 10 is a multi-time programmable memory cell. The control circuit 24 is coupled to these M multi-time programmable memory blocks 231-23M for controlling programming or erasing these M multi-time programmable memory blocks 231-23M. The row decoder 27 is coupled between the control circuit 24 and the M multi-time programmable memory blocks 231-23M. The column decoder 28 is coupled between the control circuit 24 and the M multi-time programmable memory blocks 231-23M. The flash memory device 20 is a non-volatile memory.

Please keep referring to FIG. 2. Assume that the user wants to write data into the first multi-time programmable memory block 231 of the flash memory device 20. When the first multi-time programmable memory block 231 is not written yet, the user writes data into the first multi-time programmable memory block 231 directly. At a next time when the user wants to write data into the first multi-time programmable memory block 231, the data already written in the first multi-time programmable memory block 231 needs to be erased before writing the new data.

Due to data stored in the flash memory cell 10 being determined by electrons stored in the floating gate 15, the on/off status of the flash memory cell 10 corresponds to a binary number “1” or “0”. Programming or erasing the flash memory cell 10 will damage the channel 19. Therefore, the life of the M multi-time programmable memory blocks 231-23M is restricted to the number of times of the multi-time programmable memory cell can be programmed and erased. Furthermore, erasing data of memory wastes much more time than programming.

### SUMMARY OF THE INVENTION

The claimed invention provides a method capable of improving the endurance of memory. The method includes detecting whether a record cell is the last non-programmed record cell of a set of record cells that includes the record cell. The method includes erasing a data of a corresponding set of multi-time programmable memory blocks and erasing the set of record cells, if the record cell is the last record cell of the set of record cells that includes the record cell. The method further includes programming a data of a record cell corresponding to the first non-programmed record cell in the set of record cells if the record cell is not the last non-programmed record cell of the set of record cells that includes the record cell.

The claimed invention provides a memory capable of improving endurance. The memory includes a plurality of sets of multi-time programmable memory blocks, a plurality of sets of record cells, and a control circuit. Each set of multi-time programmable memory blocks includes a plurality of multi-time programmable memory blocks. Each record cell corresponds to a multi-time programmable memory block for recording the status of the corresponding multi-time programmable memory block. The control circuit is coupled to the plurality of sets of multi-time programmable memory blocks and the plurality of sets of record cells for controlling programming or erasing the plurality of sets of multi-time programmable memory blocks according to data of the plurality of sets of record cells. Each multi-time programmable memory block in the plurality of sets of multi-time programmable memory blocks is constructed of a plurality of multi-time programmable memory cells. Each record cell in the plurality of sets of record cells is constructed of a multi-time programmable memory cell or a plurality of multi-time programmable memory cell. The memory is a non-volatile memory or a flash memory.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram of a structure of a flash memory cell according to the prior art.

FIG. 2 is a diagram of a flash memory device according to the prior art.

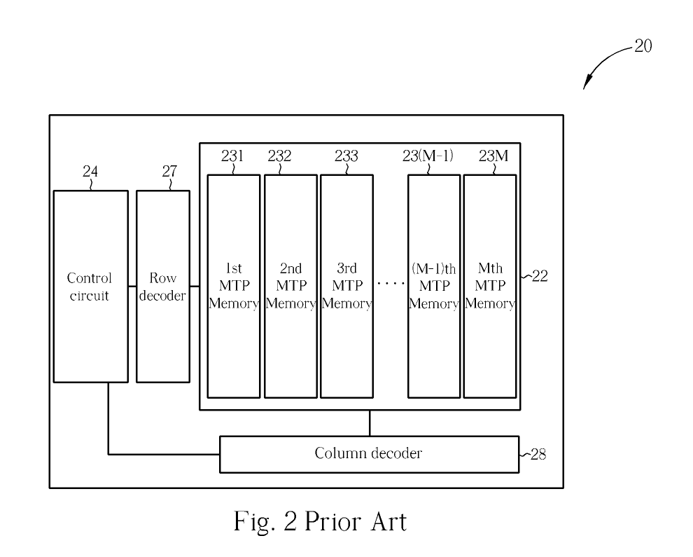

FIG. 3 is a diagram of a flash memory device according to the present invention.

FIG. 4 is a diagram of a flow illustrating a method capable of improving endurance of memory according to the present invention.

FIG. 5 is another diagram of a flow illustrating a method capable of improving endurance of memory according to the present invention.

FIG. 6 is a diagram illustrating the flow in FIG. 4.

FIG. 7 is another diagram illustrating the flow in FIG. 4.

### DETAILED DESCRIPTION

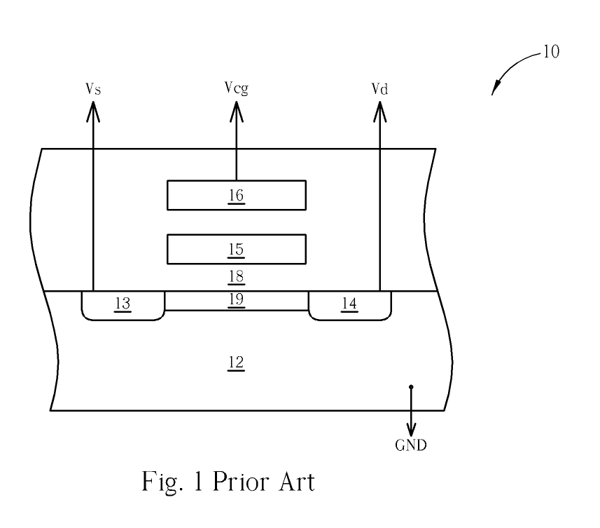

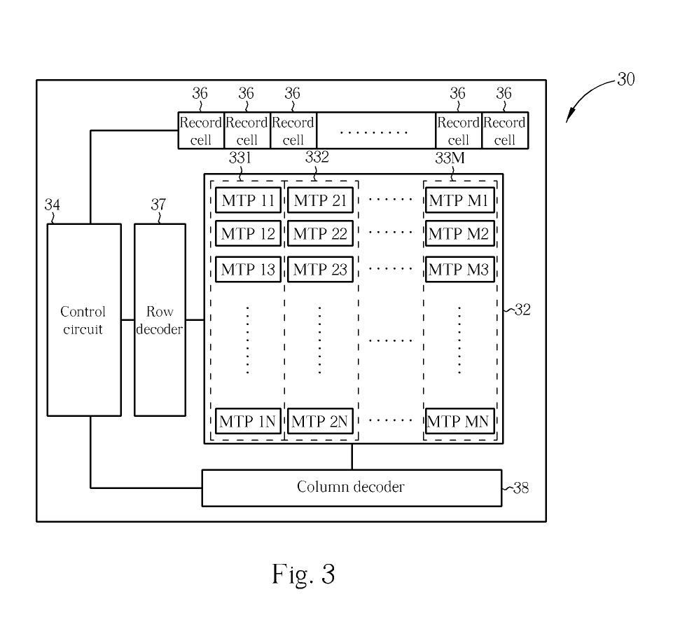

Please refer to FIG. 3 that is a diagram of a flash memory device 30 according to the present invention. The flash memory device 30 includes a multi-time programmable memory area 32, a control circuit 34, a row decoder 37, a column decoder 38, and a plurality of record cells 36. The multi-time programmable memory area 32 includes M sets of multi-time programmable memory blocks 331-33M, wherein each set of multi-time programmable memory block includes N multi-time programmable memory blocks. For example, the first set of multi-time programmable memory block 331 includes N multi-time programmable memory blocks MTP11-MTP1N. The second set of multi-time programmable memory block 332 includes N multi-time programmable memory blocks MTP21-MTP2N. The Mth set of multi-time programmable memory block 33M includes N multi-time programmable memory blocks MTPM1-MTPMN. Each programmable memory block may comprise a flash memory cell as is shown in FIG. 1. The control circuit 34 is coupled to the M sets of multi-time programmable memory blocks 331-33M for controlling programming or erasing the M sets of multi-time programmable memory blocks 331-33M. The row decoder 37 is coupled between the control circuit 34 and the M sets of multi-time programmable memory blocks 331-33M. The column decoder 38 is coupled between the control circuit 34 and the M sets of multi-time programmable memory blocks 331-33M. Each record cell of the plurality of record cells 36 corresponds to a multi-time programmable memory block for recording two statuses of the corresponding multi-time programmable memory block—programmed and non-programmed. Each record cell 36 comprises of a multi-time programmable memory cell such as the flash memory cell 10 in FIG. 1. In this embodiment, there are totally M×N multi-time programmable memory blocks MTP11-MTPMN. Therefore, there are totally M×N corresponding record cells 36. The flash memory device 30 is a non-volatile memory.

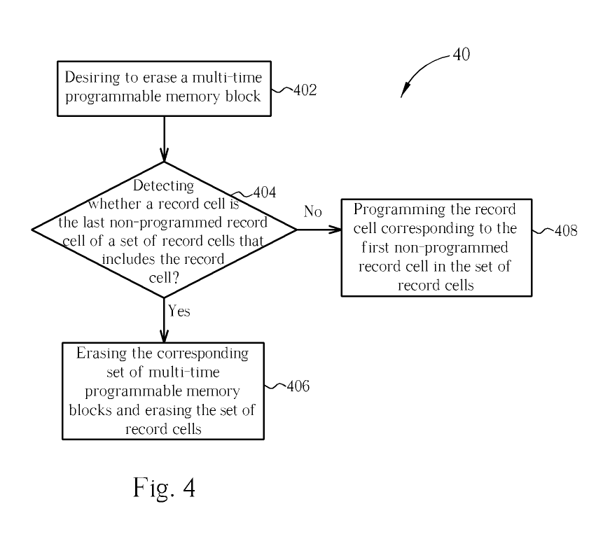

Please refer to FIG. 4. FIG. 4 is a diagram of a flow 40 illustrating a method capable of improving endurance of memory according to the present invention. The flow 40 includes the following steps:

Step 402: Desiring to erase a multi-time programmable memory block.

Step 404: Detecting whether a record cell is the last non-programmed record cell of a set of record cells that includes the record cell.

Step 406: Erasing the corresponding set of multi-time programmable memory blocks and erasing the set of record cells, if it was detected that the record cell is the last non-programmed record cell of a set of record cells that includes the record cell.

Step 408: Programming the record cell corresponding to the first non-programmed record cell in the set of record cells, if it was detected that the record cell is not the last non-programmed record cell of a set of record cells that includes the record cell.

The flow 40 is flow-processing steps of erasing a multi-time programmable memory block. If the user desires to erase the multi-time programmable memory block, in step 404 will detect whether the record cell is the last non-programmed record cell of the set of record cells that includes the record cell first. Only when the record cell is the last non-programmed record cell of the set of record cells that includes the record cell, the erase operation is executed. Otherwise, another record cell is programmed (corresponding to the first non-programmed record cell).

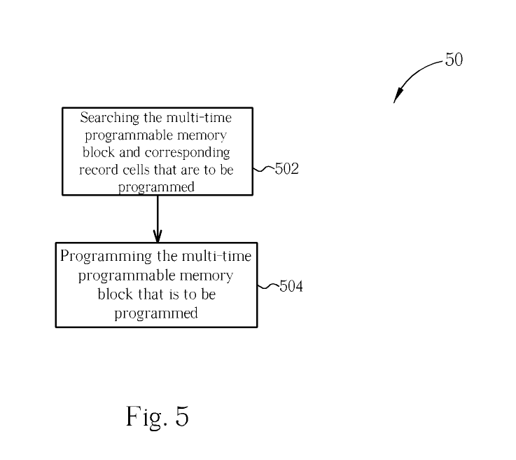

Please refer to FIG. 5. FIG. 5 is another diagram of a flow 50 illustrating a method capable of improving endurance of memory according to the present invention. The flow 50 includes the following steps:

Step 502: Searching the multi-time programmable memory block and corresponding record cells that are to be programmed.

Step 504: Programming the multi-time programmable memory block that is to be programmed.

The flow 50 is flow-processing steps of programming a multi-time programmable memory block. Programming the multi-time programmable memory block that is to be programmed according to data statuses of the plurality of sets of record cells. Furthermore, the method may restrict only one multi-time programmable memory block of the plurality of sets of multi-time programmable memory blocks to be programmed at a same time.

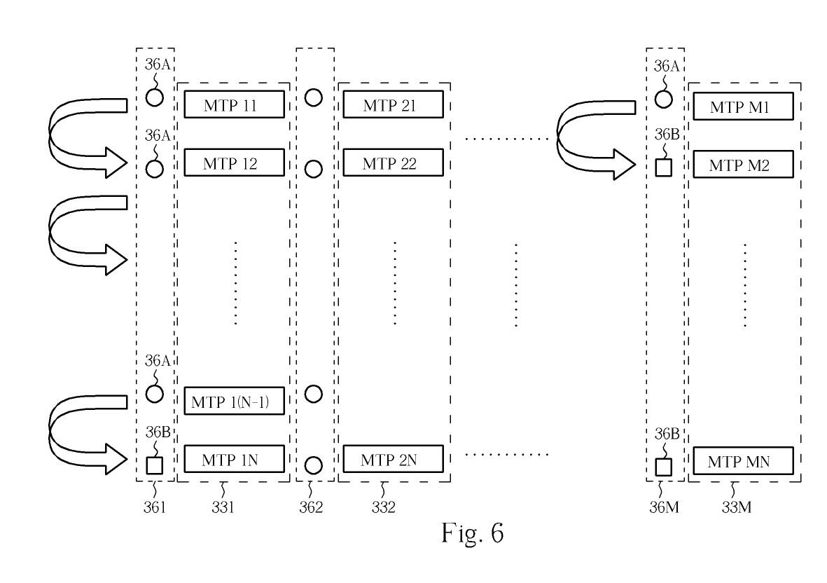

Please refer to FIG. 6 that is a diagram illustrating the flow 40 in FIG. 4. 331-33M represent the M sets of multi-time programmable memory blocks in FIG. 3. The first set of multi-time programmable memory block 331 includes N multi-time programmable memory blocks MTP11-MTP1N. The second set of multi-time programmable memory blocks 332 includes N multi-time programmable memory blocks MTP21-MTP2N. The Mth set of multi-time programmable memory blocks 33M includes N multi-time programmable memory blocks MTPM1-MTPMN. The first set of multi-time programmable memory blocks 331 corresponds with the first set of record cells 361. The second set of multi-time programmable memory blocks 332 corresponds with the second set of record cells 362. The Mth set of multi-time programmable memory block 33M corresponds with the Mth set of record cells 36M. Each set of record cells 361-36M includes N record cells. 36A and 36B represent the statuses of the corresponding multi-time programmable memory block. The status 36A represents that the corresponding multi-time programmable memory block is recorded as used, and the status 36B represents that the corresponding multi-time programmable memory block is recorded as not being used. If the user desires to erase the first set of multi-time programmable memory blocks 331, the record cell of the first set of record cells 361 corresponding to the first set of multi-time programmable memory blocks 331 being the last unused record cell. The statuses of all the other N−1 record cells of the first set of record cells 361 are all 36A (recorded as used). For this reason, the data of the first set of multi-time programmable memory block 331 and the first set of record cells 361 are erased (erase all record cells as the status 36B).

Please continue to refer to FIG. 6. If the user desires to erase the Mth set of multi-time programmable memory blocks 33M, the record cell of the Mth set of record cells 36M corresponding to the Mth set of multi-time programmable memory blocks 33M being not the last record cell is detected (the status of the first record cell is 36A, and the status of the second record cell is 36B). For this reason, programming operation is executed on the record cell. That is updating the corresponding record cell of the multi-time programmable memory block MTPM2 (update as the status 36A).

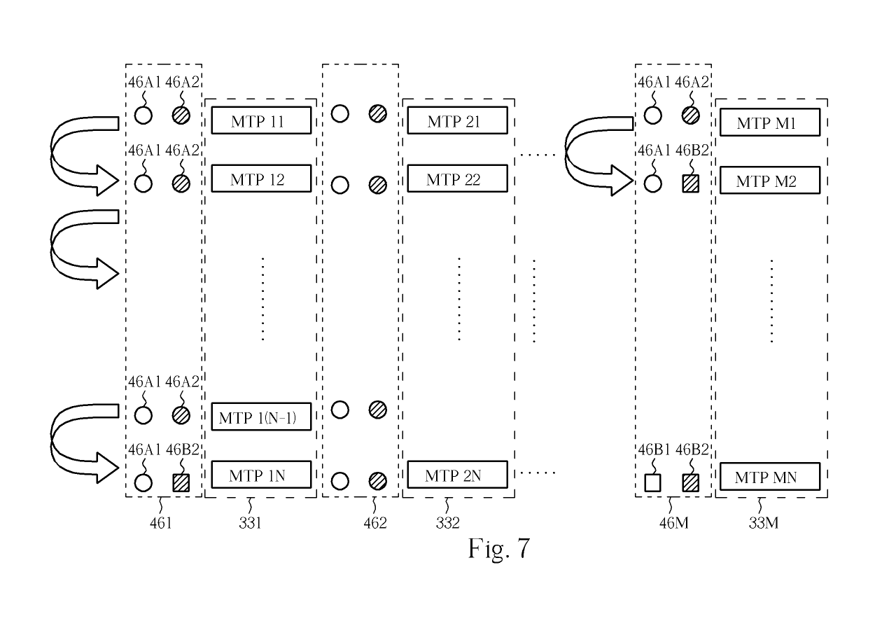

Please refer to FIG. 7 that is another diagram illustrating the flow 40 in FIG. 4. 331-33M represent the M sets of multi-time programmable memory blocks in FIG. 3. The first set of multi-time programmable memory block 331 includes N multi-time programmable memory blocks MTP11-MTP1N. The second set of multi-time programmable memory blocks 332 includes N multi-time programmable memory blocks MTP21-MTP2N. The Mth set of multi-time programmable memory block 33M includes N multi-time programmable memory blocks MTPM1-MTPMN. The first set of multi-time programmable memory block 331 corresponds with the first set of record cells 461. The second set of multi-time programmable memory blocks 332 corresponds with the second set of record cells 462. The Mth set of multi-time programmable memory block 33M corresponds with the Mth set of record cells 46M. Each set of record cells 461-46M includes 2N record cells. Each multi-time programmable memory block MTPM1-MTPMN corresponds with two record cells where the first record cell is used for recording whether the corresponding multi-time programmable memory block is programmed or not. Two statuses 46A1 and 46B1 are used to represent the record cell statuses of the first record cell. The second record cell is used for recording whether the corresponding multi-time programmable memory block is erased or not. Two statuses 46A2 and 46B2 are used to represent the record cell statuses of the second record cell. The status 46A1 of the first record cell represents that the corresponding multi-time programmable memory block is programmed, and the status 46B1 of the first record cell represents that the corresponding multi-time programmable memory block is non-programmed. The status 46A2 of the second record cell represents that the corresponding multi-time programmable memory block is erased, and the status 46B2 of the second record cell represents that the corresponding multi-time programmable memory block is not erased. If the user desires to program or erase a multi-time programmable memory block, the statues of corresponding record cells will be checked first. Programming operation or erasing operation will be executed later.

The above-mentioned embodiments illustrate but do not limit the present invention. The values M and N are not restricted to a constant value and depend on user's demand. If the value M is increased, the capacity of the flash memory device 30 can be improved. If the value N is increased, the endurance of the flash memory device 30 can be improved. Furthermore, each multi-time programmable memory block and record cell could be constructed of multi-time programmable memory cells. But the multi-time programmable memory cell is not limited to flash memory only, and could be other kinds of multi-time programmable memory cells. Each multi-time programmable memory block is not limited to corresponding to a single record cell, but can correspond to two or a plurality of record cells, depending on user's demand.

In conclusion, the present invention provides a method and related apparatus capable of improving endurance of memory. Assume that the manufacturing process of the multi-time programmable memory cells 231-23M in the flash memory device 10 is the same as the manufacture process of the multi-time programmable memory cells MTP11-MTPMN in the flash memory device 30. If the endurance of the flash memory device 10 is 1 k times, then the endurance of the flash memory device 30 can be improved to N×k times. Furthermore, the present invention can save effective erasure time due to the erasing operation being executed only when the record cell is detected as the last non-programmed record cell of a set of record cells. Otherwise, the record cell corresponding to the first non-programmed record cell in the set of record cells is programmed. Assume an erasure time is Ters and the time updating the record cell is Tpgm, then the effective erase time could be represented as (Ters+(N−1)Tpgm)/N. Because the time Tpgm is much smaller than the erase time Ters, the present invention can save the effective erase time and further improve the efficiency of the flash memory device 30.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A memory capable of improving endurance comprising:
a plurality of sets of multi-time programmable memory blocks, each set of multi-time programmable memory blocks comprising a plurality of multi-time programmable memory blocks;
a plurality of sets of record cells, each record cell corresponding to a multi-time programmable memory block for recording a status of the corresponding multi-time programmable memory block; and
a control circuit coupled to the plurality of sets of multi-time programmable memory blocks and the plurality of sets of record cells for controlling programming or erasing the plurality of sets of multi-time programmable memory blocks according to data of the plurality of sets of record cells.

2. The memory of claim 1 further comprising a column decoder coupled between the control circuit and the plurality of sets of multi-time programmable memory blocks.

3. The memory of claim 1 further comprising a row decoder coupled between the control circuit and the plurality of sets of multi-time programmable memory blocks.

4. The memory of claim 1 wherein each record cell in the plurality of sets of record cells is used for recording two statuses of the corresponding multi-time programmable memory block: programmed and non-programmed.

5. The memory of claim 1 wherein each multi-time programmable memory block in the plurality of sets of multi-time programmable memory blocks is constructed of a plurality of multi-time programmable memory cells.

6. The memory of claim 1 wherein each record cell in the plurality of sets of record cells is constructed of a multi-time programmable memory cell.

7. The memory of claim 1 wherein each record cell in the plurality of sets of record cells is constructed of a plurality of multi-time programmable memory cell.

8. The memory of claim 1 wherein the memory is a non-volatile memory.

9. The memory of claim 1 wherein the memory is a flash memory.
